(19) United States
(12) Patent Application Publication
(10) Pub. No.: US 2026/0342119 A1
(43) Pub. Date: Oct. 29, 2026

(54) VEHICLE WITH BATTERY ELECTRIC SYSTEM AND INTERLEAVED POWER MODULE

(71) Applicant: GM GLOBAL TECHNOLOGY OPERATIONS LLC, Detroit, MI (US)

(72) Inventors: Yilun Luo, Ann Arbor, MI (US); Pengwei Li, Willington, CT (US); Chandra S. Namuduri, Troy, MI (US); Dongxu Li, Troy, MI (US)

(73) Assignee: GM GLOBAL TECHNOLOGY OPERATIONS LLC, Detroit, MI (US)

(21) Appl. No.: 19/190,992

(22) Filed: Apr. 28, 2025

(51) Int. Cl. H02J 7/00; B60L 50/51; B60L 50/60; H05K 7/20

(52) U.S. Cl. CPC H02J 7/855; B60L 50/51; B60L 50/60; H05K 7/20927

(57) ABSTRACT

A power module for a battery electric system, e.g., of a vehicle, includes a voltage busbar, a printed circuit board (PCB), first and second power switch sets, and decoupling capacitors. The PCB is positioned between parallel positive and negative busbars. The first power switch set is connected to the positive busbar adjacent to a first side of the PCB, and operates as high-side switches. The second power switch set is connected to the negative busbar adjacent to a second side of the PCB, and operates as low-side switches. The busbars are situated between current paths of the high-side and low-side switches. The decoupling capacitors are connected to local voltage bus on the first side of the PCB. High-side and low-side gate driver integrated circuits may be contained in gaps or spaces separating the switch sets from the respective first and second sides of the PCB.

### INTRODUCTION

The present disclosure relates to battery electric systems having a direct current (DC) power supply, e.g., a high-voltage electrochemical battery pack. Within the battery electric system, a DC output voltage provided by the battery pack may be converted into an alternating current (AC) voltage via an inverter. The AC output voltage from the inverter is directed to phase windings of a rotary electric machine, for example an electric traction motor of a representative vehicle. The energized motor responds via rotation and transmission of torque to a coupled load. The battery electric system may also include a DC-to-DC voltage converter operable for selectively increasing or decreasing a DC voltage level on a main DC voltage bus as needed.

An interleaved power module is a specialized power conversion architecture used in high-current, higher power density applications. Modern electric vehicle propulsion systems, for instance, may use interleaved power modules within resident inverter or converter architectures. The interleaved configuration interconnects multiple parallel power stages to produce a desired output voltage. Switching control signals for the various power stages may be phase-shifted to create ripple cancellation effects. By avoiding the need to share electric current across common components, an interleaved converter is able to distribute the electric current among smaller hardware components to help reduce thermal stress.

### SUMMARY

An interleaved power module is disclosed herein for use in a battery electric system. The battery electric system in turn may be used aboard an electrified mobile or stationary system, such as but not limited to electric or hybrid electric vehicles. In particular, the power module of the present disclosure employs a folded/multi-layered printed circuit board (PCB), i.e., one having parallel switching dies constructed as set forth herein, to optimally couple loop components and thereby reduce inductance, in particular parasitic loop inductance and stray inductance. The PCB of the present disclosure is configured as a four-layer, multi-sided, power device-mounted PCB. Absent the present teachings, a controller for the power module may attempt to retard switching speeds of solid-state switches in the power module to reduce current/voltage overshoot. However, such a control action may lead to higher losses, reduced operating range (for mobile system applications), and overall performance reduction. The PCB construction of the power module as described herein is therefore intended to address these and other possible performance issues within the battery electric system.

In particular, the power module in accordance with an embodiment includes a switch output node (SW), a local voltage bus, and a multi-layered PCB positioned between positive and negative busbars of the local voltage bus. The positive busbar and the negative busbar respectively connect to a positive input node (HV⁺) and a negative input node (HV⁻). A first power switch set is connected to the positive busbar adjacent to a first side of the PCB, with the first power switch set having a first/high-side current path, e.g., a top-side in a representative configuration, between the positive input node (HV⁺) and the switch output node (SW). A second power switch set is connected to the negative busbar adjacent to a second side of the PCB, with the second power switch set having a second/low-side (e.g., a bottom-side) current path between the negative input node (HV⁻) and the switch output node (SW). A plurality of decoupling capacitors are connected to the positive busbar and the negative busbar, the local voltage bus busbar being situated between the first/high-side current path and the second/low-side current path.

In a possible embodiment, the first and second power switch sets are surface-mounted to the first and second sides of the PCB, respectively. Optionally, the high-side and low-side power switches may be embodied as metal-oxide semiconductor field effect transistors (MOSFETs), with other solid-state configurations being possible within the scope of the disclosure as set forth below.

In different implementations, the power module includes at least six of the decoupling capacitors, or possibly at least twenty-four of the decoupling capacitors. In the latter case, the power module may be configured as a three-phase (or more) multilevel converter, an example embodiment of which is described in detail below.

One or more shunt resistors or other current sensors may be mounted to the first/top side of the PCB.

In another embodiment, the power module includes a gate driver integrated circuit (IC), e.g., a high-side gate driver integrated circuit (IC) and a low-side gate driver IC in a possible configuration. The high-side and low-side gate driver ICs are placed, in a possible implementation, on a respective top and bottom side of the PCB, with symmetrical gate driver traces and overlapping gate loops through inner layers of the PCB. The first/high-side power switch set is separated from the first side of the PCB by a first space or gap, with the first gap containing the high-side gate driver IC. Similarly, the second power switch set is separated from the second/bottom side of the PCB by a second gap containing the low-side gate driver IC.

As opposed to surface mounting, the first and second power switch sets may be embedded within the PCB in an alternative construction of the power module. In such a configuration, the PCB may define a cooling channel that extends between the first and second power switch sets. The cooling channel may contain a thermally conductive cooling material for simultaneously cooling the first and second semiconductor switch sets.

A battery electric system is also disclosed herein. The battery electric system may include a main DC voltage bus, an electrochemical battery pack connectable to the main DC voltage bus, and a power module operable for powering a load, e.g., one or more electric traction motors or other electric motors, during a discharge mode of the battery pack. The power module includes a local voltage bus that is connectable to the main DC voltage bus, with the local voltage bus having positive and negative busbars arranged in respective parallel planes. The PCB in this embodiment is positioned between the positive and negative busbars. The first power switch set, which is connected to the positive bus bars adjacent to the first/top side of the PCB, is configured to operate as high-side switches of the power module. Similarly, the second power switch set is connected to the negative bus bars adjacent to a second/bottom side of the PCB. The second power switch set operates as low-side switches in the power module. The positive and negative busbars are situated between current paths of the high-side and the low-side switches. The decoupling capacitors are connected to the positive and negative busbars, e.g., on the first/top side of the PCB.

A vehicle in accordance with another aspect of the disclosure includes a vehicle body, road wheels connected to the vehicle body, and a battery electric system. The battery electric system, which is operable as a drive system for powering one or more of the road wheels to propel the vehicle, includes a main DC voltage bus, a traction battery pack connectable to the main DC voltage bus, and a polyphase, alternating current (AC) propulsion or traction motor. The battery electric system further includes a power inverter operable for energizing the electric traction motor during a discharge mode of the battery pack.

The power module in a representative embodiment of the vehicle may be used as part of the power inverter, and includes a local voltage bus connected to the main DC voltage bus. The local voltage bus includes positive and negative busbars arranged in parallel planes. The power module also includes a multi-layered PCB that is positioned between the positive and negative busbars. A first power switch set is connected to the positive busbar adjacent to a first side of the PCB, and is configured to operate as high-side switches in the power module as noted above. A second power switch set is connected to the negative busbar adjacent to a second side of the PCB, and is configured to operate as low-side switches in the power module. The busbars in this particular implementation are situated between current paths of the high-side switches and the low-side switches. At least twenty-four decoupling capacitors are connected to the local voltage bus, e.g., on the first side of the PCB. The power module in this representative implementation is configured as a three-phase multilevel converter.

The above features and advantages, and other features and attendant advantages of this disclosure, will be readily apparent from the following detailed description of illustrative examples and modes for carrying out the present disclosure when taken in connection with the accompanying drawings and the appended claims. Moreover, this disclosure expressly includes combinations and sub-combinations of the elements and features presented above and below.

### BRIEF DESCRIPTION OF THE DRAWINGS

The accompanying drawings, which are incorporated into and constitute a part of this specification, illustrate implementations of the disclosure which, taken together with the description, serve to explain the principles of the disclosure.

FIG. 1 is an illustration of a battery electric system of a representative vehicle, with the battery electric system including an interleaved power module in accordance with the present disclosure.

FIG. 2 is a schematic circuit diagram illustrating high-current and low-current paths through the power module.

FIG. 3 is a side view illustration of the power module according to a representative three-phase construction.

FIGS. 4A and 4B are respective top and bottom plan view illustrations of the power module illustrated in FIG. 3.

FIG. 5 is a plan view illustration of an alternative construction of the representative three-phase power module shown in FIG. 3.

FIG. 6 is a side view illustration of the power module according to a possible embedded construction.

FIG. 7 is a side view illustration of the power module of FIG. 6 with an integrated cooling channel.

FIG. 8 is a side view illustration of an alternative construction of the power module of FIG. 3 that includes separate gate drive integrated circuits disposed between high-side and low-side switch sets of the power module.

The present disclosure may be modified or embodied in alternative forms, with representative embodiments shown in the drawings and described in detail below. Inventive aspects of the present disclosure are not limited to the disclosed embodiments. Rather, the present disclosure is intended to cover alternatives falling within the scope of the disclosure as defined by the appended claims.

### DETAILED DESCRIPTION

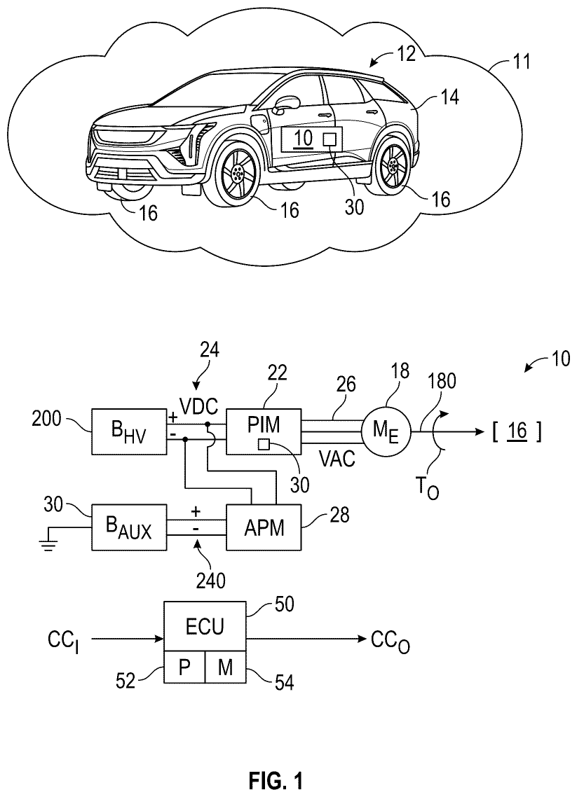

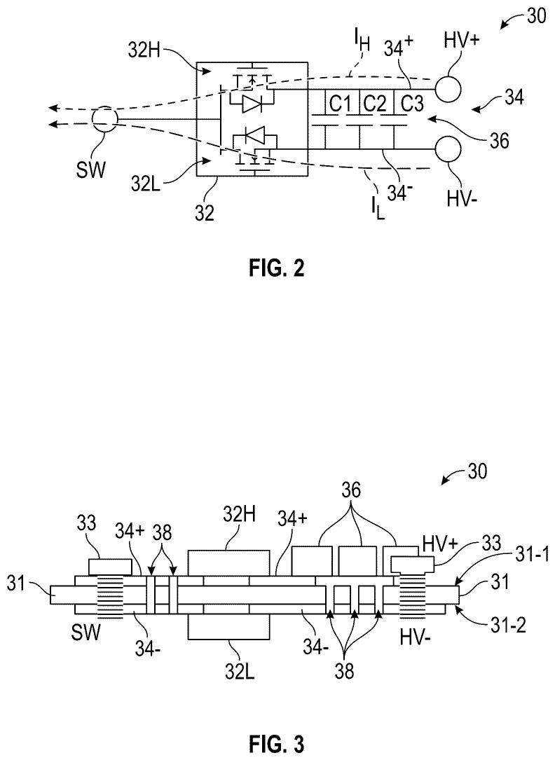

Referring to the drawings, wherein like reference numbers refer to like features throughout the several views, FIG. 1 depicts a battery electric system 10 having a power module 30 constructed in accordance with the present disclosure. As described below with reference to FIGS. 2-8, the power module 30 has a folded, multi-layered topology, i.e., one in which high-side (positive) and low-side (negative) solid-state/semiconductor power switch chips or dies are symmetrically mounted to opposing sides of a printed circuit board substrate. Thermal impedance is also reduced in some implementations via a dual-sided cooling feature. Among other possible benefits, a symmetrical gate loop is enabled by the multi-layered architecture of the power module 30 in high-speed switching circuits of the battery electric system 10 to reduce stray inductance during switching operations, which in turn minimizes switching losses and electromagnetic interference. Such benefits are gained herein through the principle of magnetic field cancellation.

The battery electric system 10 of FIG. 1 in a possible scenario may be used as part of a mobile system 11 such as a motor vehicle 12, e.g., a (full) battery electric vehicle as shown in FIG. 1 or a hybrid electric vehicle. In such an embodiment, the motor vehicle 12 may include a vehicle body 14 connected to a set of road wheels 16. The battery electric system 10 is operable for energizing one of more of the road wheels 16 to propel the motor vehicle 12. Other mobile systems 11 may be envisioned within the scope of the present disclosure, such as but not limited to robots, plant equipment, mobile platforms, farm equipment, aircraft, rail vehicles/trains, boats, etc. Stationary versions of the mobile system 11 may likewise benefit from the present teachings, for instance hoists, conveyor systems, and the like. For illustrative consistency, the battery electric system 10 will be described hereinafter as being an integral system of the representative motor vehicle 12 of FIG. 1 without limiting use of the battery electric system 10 to vehicular applications.

The battery electric system 10 includes a high-voltage electrochemical battery pack (B_{HV}) 20, e.g., about 400V to about 800V in a representative embodiment, and a main direct current (DC) voltage bus (VDC) 24 having positive and negative voltage rails (+, −). The battery pack 20 is connectable to the main DC voltage bus 24 via a set of relays or contactors (not shown). Although omitted from FIG. 1 for illustrative simplicity, the battery pack 20 includes an application-suitable number of electrochemical battery cells, for instance a lithium-ion battery such as lithium-ion nickel manganese cobalt (NMC), lithium-ion nickel cobalt aluminum (NCA), lithium iron phosphate (LFP), etc. Such a battery pack 20 may be connected to/disconnected from the main DC voltage bus 24 as needed via operation of the above-noted contactors, for instance when the motor vehicle 12 is turned off/powered down, in response to threshold forces on the motor vehicle 12, during an electrical fault, or before performing maintenance on high-voltage components.

The main DC voltage bus 24 in a possible construction may be connected to a power inverter module (PIM) 22, with the PIM 22 including the power module 30 in one or more embodiments. The PIM 22 may be connected to a polyphase alternating current (AC) electric traction motor (M_{E}) 18, with the PIM 22 operable for energizing phase windings 19 of the electric traction motor 18 during a discharge mode of the battery pack 20. In such an implementation, the battery electric system 10 may include an AC voltage bus 26 providing an AC voltage (VAC) to the electric traction motor 18. The electric traction motor 18 in such a construction includes individual phase windings 19, for instance nominal (a, b, c) or (u, v, w) phases in a representative three-phase construction. Such phase windings 19 are wired/connected to the AC voltage bus 26.

In the representative vehicular embodiment illustrated in FIG. 1, a rotatable output member 180 of the electric traction motor 18 is connected to a load in the exemplary form of one or more of the road wheels 16. Delivery of motor torque (arrow T_{O}) to the road wheels 16 via the output member 180 via discharging of the battery pack 20 has the effect of energizing the PIM 22. This in turn causes rotation of a rotor (not shown) of the electric traction motor 18 to rotate the road wheels 16 and thereby propel the motor vehicle 12.

The battery electric system 10 illustrated in FIG. 1 may include additional components depending on its configuration. For instance, an auxiliary power module (APM) 28, i.e., a DC-to-DC converter, which may include the power module 30 in some implementations, may be connected to the main DC voltage bus 24 and an auxiliary voltage bus 240. The auxiliary voltage bus 240 may be connected to an auxiliary battery (B_{AUX}) 200, for instance a nominal 12-15V lead-acid starting battery. Thus, the voltage level of the auxiliary voltage bus 240 is substantially lower than the high-voltage levels present on the DC voltage bus 24.

The battery electric system 10 may also include an electronic control unit (ECU) 50 operable for controlling the various components of the battery electric system 10 via electronic output signals (arrow CC_{O}). For example, the ECU 50 may be programmed to control an ON/OFF switching state of constituent solid-state switches of the power module 30 as explained in detail below with reference to FIGS. 2-8. The ECU 50 may also be configured to control the operational state of the electric traction motor 18 via the power module 30 in response to generated or received electronic input signals (arrow CC_{I}), for instance a driver-requested or autonomously-requested output torque during propulsion modes of the motor vehicle 12. The ECU 50 of FIG. 1 may be equipped with one or more processors (P) 52 in the form of, e.g., an application specific integrated circuit (ASIC), a field-programmable gate array (FPGA), a central processing unit, etc. The ECU 50 also includes computer-readable storage medium (or media), i.e., memory (M) 54, in the form of non-transitory memory component(s) such as read only memory (ROM), optical or magnetic media, etc.

The non-transitory memory components of the memory 54 are configured to store machine readable instructions in the form of one or more software or firmware programs or routines, combinational logic circuit(s), input/output circuit(s) and devices, signal conditioning and buffer circuitry and other components that may be accessed by one or more processors to provide a described functionality. Input/output circuit(s) and devices include analog/digital inverters and related devices that monitor inputs from sensors, with such inputs monitored at a preset sampling frequency or in response to a triggering event. Software, firmware, programs, instructions, control routines, code, algorithms and similar terms mean controller-executable instruction sets including calibrations and look-up tables.

Referring now to FIG. 2, operation of the power module 30 when energizing the electric traction motor 18 of FIG. 1 or another load is depicted in circuit diagram form for illustrative clarity. The power module 30 includes a local voltage bus 34 that is ultimately connected to the main DC voltage bus 24 of FIG. 1, with the power module 30 having a positive busbar 34⁺ and a negative busbar 34⁻ arranged in parallel planes. Positive and negative high-voltage connection nodes are also respectively labeled HV⁺ and HV⁻ for clarity.

As part of the power module 30, a switching circuit 32 includes first and second semiconductor-based/solid-state power switch sets 32H and 32L, with “H” and “L” representing “high-side” (connected to the positive busbar 34⁺) and “low-side” (connected to the negative voltage rail 34⁻). A plurality of decoupling capacitors 36 (e.g., DC links capacitors C1, C2, and C3) are connected to the local voltage bus 34, i.e., across the positive busbar 34⁺ and the negative voltage rail 34⁻ as shown. The respective first and second power switch sets 32H and 32L likewise are connected to the respective positive and negative busbars 34⁺ and 34⁻ . An output node (SW) of the power module 30 is illustrated at an output side of the switching circuit 32.

Different high-side and low-side current paths (I_{H} and I_{L}) are shown through the switching circuit 32. As described below, the positive busbar 34⁺and negative busbar 34⁻ are situated between the two current paths (I_{H} and I_{L}) of the high-side and low-side switches, i.e., the respective first and second power switch sets 32H and 32L. The current paths (I_{H} and I_{L}) are carried through the positive and negative busbars 34⁺, 34⁻ on opposing sides, with transient current ripple in the decoupling capacitors 36.

As appreciated by those skilled in the art, interleaved inverter topologies have a power loop in which current of a relatively high magnitude or amplitude (“high current”) flows to positive rail-connected/high-side (HS) power modules, to negative rail-connected/low-side (LS) power modules, and back again. Loops of this type tend to generate magnetic fields and form undesirable parasitic inductances. With the adoption of higher-temperature, faster-switching solid-state power switches, such as silicon carbide (SiC) and gallium nitride (GaN) metal-oxide semiconductor field effect transistors (MOSFETs) in emerging inverter circuit architectures, parasitic inductances on the order of about 15 nano-Henries (nH) or less may still cause relatively large induced voltages or current spikes, potentially compromising the structural integrity or function of the inverter or converter in which the switching circuit 32 is used. The same parasitic inductances may lead to ringing and electromagnetic interference.

Referring to FIG. 3, the power module 30 of the various embodiments described below is based on a folded or multi-layered printed circuit board (PCB) 31. The PCB 31 thus has opposing first and second sides 31-1 and 31-2 arranged in parallel planes. From the non-limiting perspective of FIG. 3, first side 31-1 is a top or upper surface of the PCB 31, while the second side 31-2 is a bottom or lower surface of the PCB 31. However, the orientation of the power module 30 may differ based on the application, and thus the upper/lower designation is application specific. The PCB 31 is positioned between the positive busbar 34⁺ and the negative busbar 34⁻ , with the local voltage bus 34 connected to the PCB 31 via terminals 33, for instance threaded fasteners as shown, rivets, or using soldered or welded joints. While the positive busbar 34⁺ is present at the first side 31-1 of the PCB 31 and the negative busbar 34⁻ is present at the second side 31-2 of the PCB 31, portions of the negative busbar 34⁻ are also present on the first side 31-1. That is, conductive vias 38 such as copper traces or fills may extend between the first and second sides 31-1 and 31-2 of the PCB 31 as shown to connect segments or portions of the negative busbar 34⁻ located on the opposing first and second sides 31-1 and 31-2. The negative busbar 34⁻ is thus considered herein to be multi-tiered and available on both sides of the PCB 31.

In this configuration, the first power switch set 32H, which is connected to the positive busbar 34⁺ adjacent to the first side 31-1 of the PCB 31, is configured to operate as high-side switches in the power module 30 as noted above. Similarly, the second power switch set 34L is connected to the negative busbar 34⁻ adjacent to the second side 31-2 of the PCB 31. The decoupling capacitors 36 are connected to the positive and negative busbars 34⁺ and 34⁻ on the first side 31-1 of the PCB 31 in this implementation.

In the non-limiting embodiment of FIG. 3, the first power switch set 32H and the second power switch set 32L are surface-mounted to the first side 31-1 and the second side 31-2 of the PCB 31, respectively. The high-side switches 32H and the low-side switches 32L may be configured as metal-oxide semiconductor field effect transistors (MOSFETs) as shown in the representative construction of FIG. 2, or possibly as insulated gate bipolar transistors (IGBTs), thyristors, junction field-effect transistors (JFETs), or another application-suitable solid-state switch in other implementations. The MOSET embodiment of FIG. 3 is therefore non-limiting.

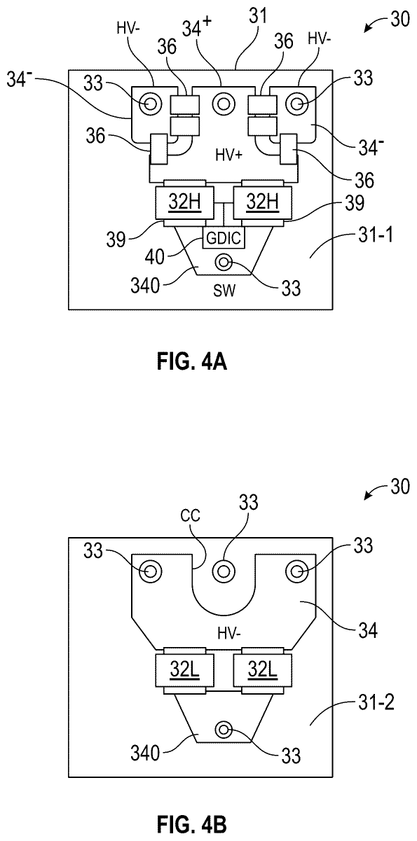

A simplified top-view and bottom-view illustration of the power module 30 is illustrated in FIGS. 4A and 4B, respectively, with the local voltage bus 34 connected to the PCB 31 via the terminals 33. Rounded corners (CC), as shown for instance in FIG. 4B, reduce electrical field strength in the gap between the positive busbar 34⁺ and the negative busbar 34⁻. The positive busbar 34⁺ and negative busbar 34⁻ are visible from the perspective of FIG. 4A, with the negative busbar 34⁻ shown in FIG. 4B (i.e., the underside of the power module 30), with the exposed portions of the negative busbar 34⁻ at the first side 31-1 of the PCB 31 connected to remaining portions of the negative busbar 34⁻ by the vias 38 (FIG. 3). As noted above with reference to FIG. 3, the decoupling capacitors 36 are connected to the voltage bus 34, e.g., on the first side 31-1 of the PCB 31. Six of the decoupling capacitors 36 are used in this exemplary configuration to interconnect the respective positive and negative bus bars 34⁺ and 34⁻.

In the configuration of FIGS. 4A and 4B, the power module 30 may include current sensors 39 mounted to the first side 31-1 of the PCB 31. For instance, the current sensors 39 may include a pair of the current sensors 39 in the form of integrated shunt resistors (one for each of the first and second power switch sets 32H and 32L), or another application-suitable current sensing element, e.g., Hall Effect or flux gate current sensors, magneto-resistive sensors, etc.

The representative power module 30 topology illustrated in FIG. 4A may also include a gate driver integrated circuit (GDIC) 40, which is ideally positioned in close proximity to the chips/dies hosting the first/high-side power switch set 32H and the second/low-side power switch set 32L. The GDIC 40 is operable for controlling the ON/OFF states of the MOSFETs or other solid-state switches of the switch sets 32H and 32L, possibly in conjunction with the ECU 50 of FIG. 1. As appreciated by those skilled in the art, a gate driver such as the representative GDIC 40 is operable for amplifying power signals from the ECU 50 or other external controller when driving the gate terminals of the MOSFETs in the non-limiting configuration of FIG. 2. The GDIC 40 may also perform circuit protection functions, e.g., current limiting, thermal protection, etc.

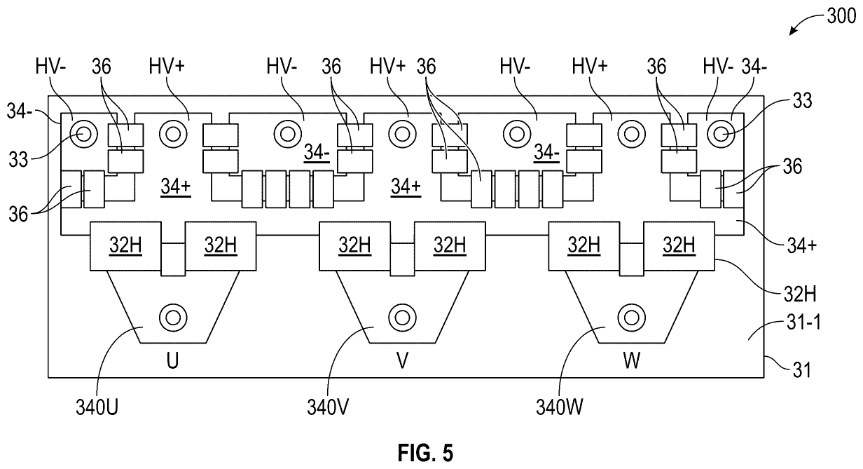

Referring briefly to FIG. 5, the present teachings and associated benefits may be extended to a polyphase AC application using a power module 300. For example, the power module 300 may be constructed as a three-phase multilevel converter in a representative implementation. While an exemplary three-phase implementation is illustrated in FIG. 5, those skilled in the art will appreciate that the circuit topology may be extended to include additional phases within the scope of the disclosure, e.g., six-phase, nine-phase, etc. Such higher-phase implementations may be used in the vehicular embodiment of FIG. 1 for reduced torque ripple and higher fault tolerance, albeit at the expense of increased circuit complexity.

As with the embodiment of FIGS. 3 and 4A-4B, the symmetrical layout of the power module 300 sets its local voltage busbar 34 between the high-side and low-side current paths I_{H}, I_{L} of FIG. 2 for optimal current sharing between parallel dies. In this circuit topology, twenty-four decoupling capacitors 36 are used to interconnect the positive and negative busbars 34⁺ and 34⁻. Output busbars 340U, 340V, and 340W (for a nominal u, v, w phase representation) may be connected to the phase windings 19 of FIG. 1 to power the electric traction motor 18 in a representative vehicular application, e.g., EV propulsion. Although omitted for illustrative simplicity, the power module 300 may also include the above-described GDIC 40 and the current sensors 39 shown in FIG. 4A. Also, gate loop traces between the parallel power switches 32H (FIG. 4A) are also symmetrically designed on the PCB 31 to improve dynamic current sharing balancing.

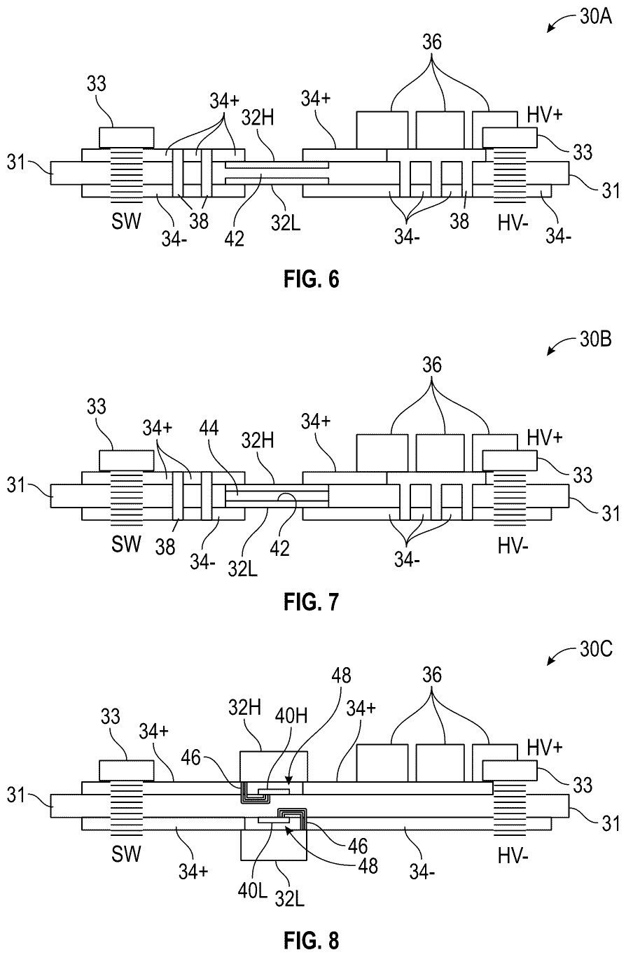

The above-described power modules 30 and 300 may be alternatively implemented by embedding the first (high-side) power switch set 32H and the second (low-side) power switch set 32L within the PCB 31. This alternative construction is illustrated in FIGS. 6 and 7. Embedding of switch dies within the thickness of the PCB 31 may further improve the field cancellation effect of the proposed folded/symmetrical design and parallel high/low current paths described above with reference to FIGS. 2-5. Among other benefits, embedding of the may reduce equivalent series inductance (ESL) to reduce voltage/current overshoot, ringing, and electromagnetic interference within the power module 30. Embedding of the first and second power switch sets 32H and 32L may also reduce fabrication steps by utilizing an embedded PCB manufacturing process.

In contrast with the surface-mounted solution of FIG. 3, in which the respective first and second power switch sets 32H and 32L are mounted to the positive busbar 34⁺ and the negative busbar 34⁻ on opposing first and second sides 31-1 and 31-2 of the PCB 31, the topology of FIG. 6 (i.e., power module 30A) and FIG. 7 (i.e., power module 30B) include a gap 42 that is defined by the PCB 31 between the first and second power switch sets 32H and 32L. FR-4 or other materials of construction of the PCB 31 fills the gap 42 in the FIG. 6 embodiment.

In contrast to the power module 30A of FIG. 6, the PCB 31 of the power module 30B of FIG. 7 defines an elongated cooling channel 42C that extends between and is parallel to a respective plane of the first power switch set 32H and the second power switch 32L to aid in their double-sided cooling. The elongated cooling channel 32C is filled with a thermally-conductive material in this configuration.

The higher power density enabled by the folded/two-sided design set forth herein may lead to elevated temperatures proximate the first and second power switch sets 32H and 32L. The power module 30B of FIG. 7 therefore fills the gap 42 with a suitable thermally conductive material 44 of a different composition than the PCB 31. The presence of the thermally conductive material 44 may help optimize dissipation of generated heat from high-speed switching and enable local cooling of the first/high-side power switch set 32H and the second/low-side power switch set 32L during their operation. Materials of construction of the thermally conductive material 44 may vary with the application, available space in the gap 42, expected temperatures and thermal gradients, and other factors. Representative configurations of the thermally conductive material 44 include, e.g., conductive pads of copper or other materials having a low thermal resistance path, miniature heat pipes operable for conducting heat to an external heat sink (not shown), phase change materials (PCMs), ceramic-embedded epoxy material, graphite or graphene layers, etc.

Referring to FIG. 8, as noted above with reference to FIGS. 4A and 4B, it may be desirable to place the gate driver IC 40 in close proximity to the controlled solid-state switches of the respective first and second power switch sets 32H and 32L. As loop size is proportional to the linear distance between the gate driver IC 40 and the chips on which the first and second power switch sets 32H and 32L are disposed, it is preferrable to reduce the loop size to the extent possible. Proximate placement helps reduce gate loop resistance and parasitic inductance, and also improves power density relative to topologies that extend traces between the controlled switches and the gate driver IC 40. Thus, the placement of FIG. 8 compliments benefits of the folded/dual-sided and symmetrical configuration of the PCB 31.

In the illustrated configuration of FIG. 8, a power module 30C replaces the gate driver IC 40 of FIG. 4A with a high-side gate driver IC 40H and a low-side gate driver IC 40L, which together form an inner gate driver circuit within the power module 30C. The first power switch set 32H in this implementation is separated from the first side 30-1 of the PCB 31 by a first gap 48-1 containing the high-side gate driver IC 40H. Similarly, the second power switch set 32L is separated from the second side 30-2 of the PCB 31 by a second gap 48-2 containing therein the low-side gate driver IC 40L. Separate gate-source loop traces 46 extend between the high-side gate driver IC 40H and the low-side gate driver IC 40L and the respective first/high-side power switch set 32H and second/low-side power switch set 32L.

In the power module 30C illustrated in FIG. 8, the overlapping nature of the gate-source loop traces 46 further contributes to reduced loop inductance in accordance with the disclosure. Optionally, the high-side gate driver IC 40H and the low-side gate driver IC 40L may be shielded with a thin copper plate 48, which may be applied to the first side 31-1 and the second side 31-2 within the first and second gaps. Such a construction may be used to further reduce electromagnetic interface.

The disclosed solutions as illustrated in FIGS. 1-8 and disclosed hereinabove are operable for reducing voltage/current overshoot for reduced device stress of the power module 30 and its several variations, i.e., power modules 300, 30A, 30B, and 30C, including the positive and negative busbars 34⁺ and 34⁻ and the decoupling capacitors 29. The proposed circuit topologies enable the use of smaller capacitors 29 and busbars 34⁻ and 34+ relative to competing architectures, along with the use of switching dies having a lower voltage rating. Among other benefits, the power module 30 in its various configurations may help reduce ringing, radiative/conductive electromagnetic interference, higher switching speeds, and improved heat rejection. These and other attendant benefits of the foregoing disclosure will be readily appreciated by those of ordinary skill in the art now having the benefit of the present disclosure.

For purposes of the present description, unless specifically disclaimed, use of the singular includes the plural and vice versa, the terms “and” and “or” shall be both conjunctive and disjunctive, and the words “including,” “containing,” “comprising,” “having,” and the like shall mean “including without limitation.” Moreover, words of approximation such as “about,” “almost,” “substantially,” “generally,” “approximately,” etc., may be used herein in the sense of “at, near, or nearly at,” or “within 0-5% of,” or “within acceptable manufacturing tolerances,” or logical combinations thereof.

The detailed description and the drawings or figures are supportive and descriptive of the present teachings, but the scope of the present teachings is defined solely by the claims. While some of the best modes and other examples for carrying out the present teachings have been described in detail, various alternative designs and aspects of the disclosure exist for practicing the present teachings defined in the appended claims.

What is claimed is:

1. A power module comprising:
a switch output node (SW);
a local voltage bus having a positive busbar and a negative busbar arranged on respective parallel planes, the positive busbar and the negative busbar being respectively connected to a positive input node (HV⁺) and a negative input node (HV⁻);
a printed circuit board (PCB) positioned between the positive busbar and the negative busbar;
a first power switch set connected to the positive busbar adjacent to a first side of the PCB, the first power switch set having a first/high-side current path between the positive input node (HV⁺) and the switch output node (SW);
a second power switch set connected to the negative busbar adjacent to a second side of the PCB, the second power switch set having a second/low-side current path between the negative input node (HV⁻) and the switch output node (SW); and
a plurality of decoupling capacitors connected to the positive busbar and the negative busbar, the local voltage bus busbar being situated between the first/high-side current path and the second/low-side current path.

2. The power module of claim 1, wherein the first power switch and the second power switch set are surface-mounted to the first side of the PCB and the second side of the PCB, respectively.

3. The power module of claim 1, wherein the first power switch set and the second power switch set are configured as metal-oxide semiconductor field effect transistors (MOSFETs).

4. The power module of claim 1, wherein the plurality of decoupling capacitors include at least six decoupling capacitors.

5. The power module of claim 4, wherein the at least six decoupling capacitors include twenty-four decoupling capacitors, and wherein the power module is configured as a three-phase multilevel converter.

6. The power module of claim 1, further comprising:
one or more current sensors mounted to the PCB.

7. The power module of claim 6, wherein the one or more current sensors include one or more shunt resistors.

8. The power module of claim 1, further comprising:
a gate driver integrated circuit (IC) connected to the PCB in proximity to the first power switch set and the second power switch set.

9. The power module of claim 8, wherein the gate driver IC includes:
a high-side gate driver integrated circuit (IC); and
a low-side gate driver IC, and wherein:
the first power switch set is separated from the first side of the PCB by a first gap containing therein the high-side gate driver IC; and
the second power switch set is separated from the second side of the PCB by a second gap containing therein the low-side gate driver IC.

10. The power module of claim 1, wherein the first power switch set and the second power switch set are embedded within the PCB.

11. The power module of claim 10, wherein:
a gap is defined in the PCB between the first power switch set and the second power switch set; and
the gap is filled with a thermally conductive material operable for cooling the first power switch set and the second power switch set.

12. A battery electric system for powering a load, comprising:
a main direct current (DC) voltage bus;
a battery pack connectable to the DC voltage bus; and
a power module operable for powering the load during a discharge mode of the battery pack, the power module comprising:
a switch output node (SW);
a local voltage bus connected to the main DC voltage bus and having a positive busbar and a negative busbar arranged on respective parallel planes, the positive busbar and the negative busbar being respectively connected to a positive input node (HV⁺) and a negative input node (HV⁻);
a printed circuit board (PCB) positioned between the positive busbar and the negative busbar;
a first power switch set connected to the positive busbar adjacent to a first side of the PCB, the first power switch set having a first/high-side current path between the positive input node (HV⁺) and the switch output node (SW);
a second power switch set connected to the negative busbar adjacent to a second side of the PCB, the second power switch set having a second/low-side current path between the negative input node (HV⁻) and the switch output node (SW); and
a plurality of decoupling capacitors connected to the positive busbar and the negative busbar, the local voltage bus being situated between the first/high-side current path and the second/low-side current path.

13. The battery electric system of claim 12, further comprising:
the load, wherein the load includes an electric motor.

14. The battery electric system of claim 13, wherein the electric motor is a polyphase alternating current (AC) traction motor, and wherein the power module is configured as a three-phase multilevel converter having, as the plurality of decoupling capacitors, a set of twenty-four decoupling capacitors.

15. The battery electric system of claim 12, wherein the power module includes a gate driver integrated circuit (IC) having a high-side gate driver IC and a low-side gate driver IC, wherein:
the first power switch set is separated from the first side of the PCB by a first gap containing therein the high-side gate driver IC; and
the second power switch set is separated from the second side of the PCB by a second gap containing therein the low-side gate driver IC.

16. The battery electric system of claim 12, wherein:
the first power switch set and the second power switch set are embedded within the PCB.

17. The battery electric system of claim 16, wherein:
the PCB defines an elongated cooling channel that extends between and parallel to a respective plane of the first power switch set and the second power switch; and
the elongated cooling channel is filled with a thermally-conductive material.

18. A vehicle comprising:
a vehicle body;
a set of road wheels connected to the vehicle body; and
a battery electric system operable for powering one or more road wheels of the set of road wheels to propel the vehicle, the battery electric system including:
a main direct current (DC) voltage bus;
a battery pack connectable to the main DC voltage bus;
a polyphase alternating current (AC) electric traction motor having an output member connected to the one or more road wheels; and
a power module connected to and operable for energizing the electric traction motor during a discharge mode of the battery pack, the power module comprising:
a switch output node (SW);
a local voltage bus connected to the main DC voltage bus and having a positive busbar and a negative busbar arranged on respective parallel planes, the positive busbar and the negative busbar being respectively connected to a positive input node (HV⁺) and a negative input node (HV⁻);
a printed circuit board (PCB) positioned between the positive busbar and the negative busbar;
a first power switch set connected to the positive busbar adjacent to a first side of the PCB, the first power switch set having a first/high-side current path between the positive input node (HV⁺) and the switch output node (SW);
a second power switch set connected to the negative busbar adjacent to a second side of the PCB, the second power switch set having a second/low-side current path between the negative input node (HV⁻) and the switch output node (SW); and
at least twenty-four decoupling capacitors connected to the local voltage bus on the first side of the PCB, wherein the power module is configured as a three-phase multilevel converter.

19. The vehicle of claim 18, wherein the power module comprises:
a high-side gate driver integrated circuit (IC); and
a low-side gate driver IC, wherein:
the first power switch set is separated from the first side of the PCB by a first gap containing therein the high-side gate driver IC; and
the second power switch set is separated from the second side of the PCB by a second gap containing therein the low-side gate driver IC, wherein the first power switch set and the second power switch set are embedded within the PCB.

20. The vehicle of claim 19, wherein the PCB defines a cooling channel that extends between the first power switch set and the second power switch that are embedded within the PCB.
